(19) United States
(12) Patent Application Publication
(10) Pub. No.: US 2008/0315914 A1
(43) Pub. Date: Dec. 25, 2008

(54) Data transmission device and method thereof

(75) Inventors: Jang-Jin Nam, Yongin-si (KR); Tae-Jin Kim, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/149,885

(22) Filed: May 9, 2008

(30) Foreign Application Priority Data
May 15, 2007 (KR) 10-2007-0046914

(51) Int. Cl. H03K 19/003

(52) U.S. Cl. 326/30

(57) ABSTRACT

A data transmission device may include a transmission chip, a plurality of reception chips and/or a pair of transmission lines. The transmission chip may transmit data and the reception chips may receive the data from the transmission chip. One of the plurality of reception chips may provide a corresponding terminal resistance when it receives the data. The transmission lines may be coupled between the transmission chip and the reception chips, and the transmission lines may have a daisy-chain configuration. Therefore, a data transmission device may provide a fixed terminal resistance in impedance matching and increase a transmission speed.

### PRIORITY STATEMENT

This application claims priority under 35 USC § 119 to Korean Patent Application No. 2007-0046914 filed on May 15, 2007 in the Korean Intellectual Property Office (KIPO), the disclosure of which is incorporated herein in its entirety by reference.

### BACKGROUND

A data transmission device such as a flat display device may use a multi-drop configuration in which several chips are simultaneously connected to a common channel so as to increase a data transmission capacity.

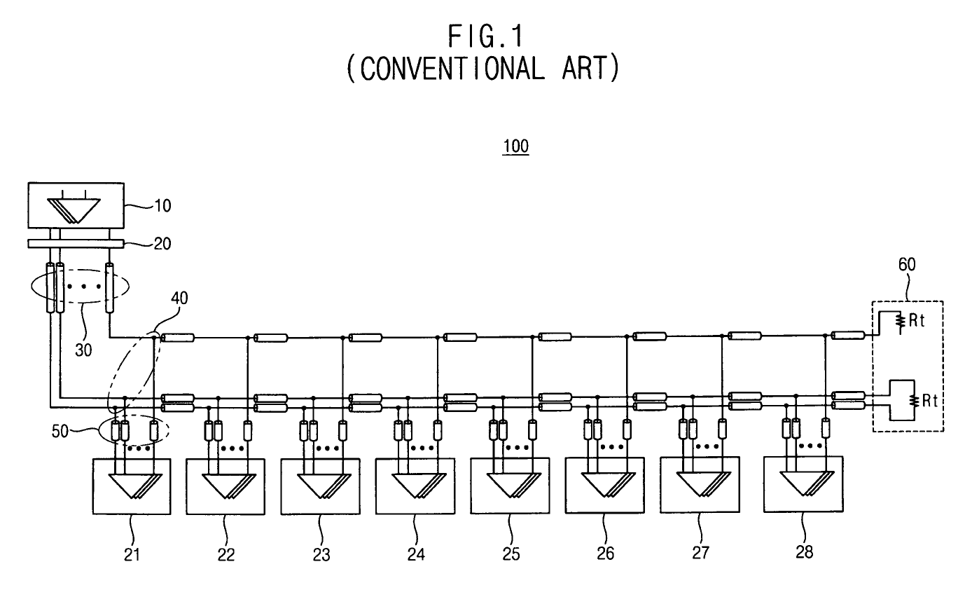

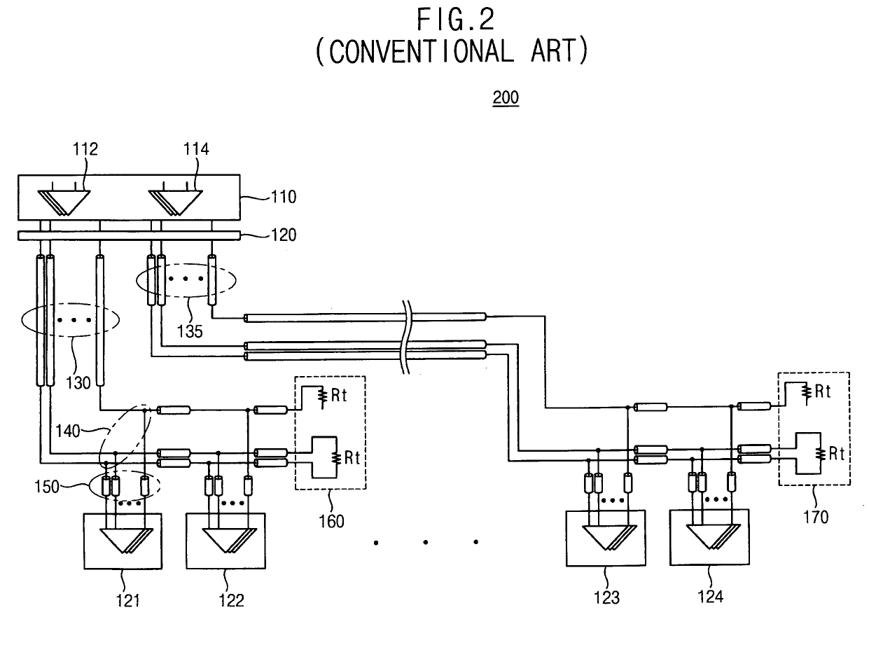

FIG. 1 is a block diagram illustrating a conventional data transmission device of multi-drop configuration.

Referring to FIG. 1, the conventional data transmission device may include a transmission unit 10, a connector 20, a plurality of transmission lines 30, a plurality of reception units 21 through 28, and a termination unit 60. The reception unit 21 may be connected to the transmission lines 30 through via-contacts 40 and stubs 50. The termination unit 60 may include one or more termination resistors Rt and may be connected to the plurality of transmission lines 30.

A bandwidth of a data reception device may be restricted by a bandwidth of the transmission lines 30 even though a data reception bandwidth of the reception units 21 through 28 may be as wide as several hundred megabits per second (Mbps).

A characteristic impedance mismatch of the transmission lines 30 may also limit a bandwidth of a transmission channel. A valid impedance of the termination resistor Rt may be less than the characteristic impedance (Zo) due to an input capacitance of the reception units 21 through 28 even though the characteristic impedance (Zo) of the transmission lines 30 may be designed to be equal to the termination resistor Rt. Degradation of a termination effect due to an embodiment of the termination resistor Rt on a printed circuit board may also limit the bandwidth of the transmission channel.

Noise of a reception unit far from the termination resistor Rt may be increased in proportion to a distance between the reception unit and the termination resistor Rt due to a reflected wave when the termination resistor Rt is close to the last reception unit 28.

Discontinuity of the via-contacts 40 and length variation of the stubs 50 may also limit the bandwidth of the transmission channel.

FIG. 2 is a block diagram illustrating another conventional data transmission device of multi-drop configuration.

Referring to FIG. 2, the conventional data transmission device may include a transmission unit 110, a connector 120, transmission lines 130 and 135, and a termination unit 170. The transmission unit 110 may include transmission chips 112 and 114, where the transmission line 130 may connect the transmission chip 112 with reception units 121 and 122, and the transmission line 135 may connect the transmission chip 114 with reception units 123 and 124. The reception unit 121 may be connected to the transmission line 130 through via-contacts 140 and stubs 150. The reception units 122, 123 and 124 may be connected to the corresponding transmission lines 130 and 135 in the same configuration as the connection of the reception unit 121. The termination unit 170 may include one or more termination resistors Rt and may be connected to the corresponding transmission lines 130 and 135.

In a multi-drop bus, two methods may be adopted so as to increase a data bandwidth. A first method may be increasing a number of data lines and a second method may be decreasing a number of chips that are connected to the multi-drop bus.

The first method may increase a valid data transmission bandwidth of a system by increasing the number of the data lines even though a transmission speed per data line is not increased. The second method may increase a valid data transmission bandwidth of a system by limiting a number of chips connected to the same bus and increasing the transmission speed per data line. However, the second method may also cause problems in impedance matching of termination resistors, the via-contacts and the stubs.

### SUMMARY

Accordingly, example embodiments may be provided to obviate one or more problems due to limitations and disadvantages of the related art.

Example embodiments may provide a data transmission device which contains a terminal resistance only in a reception chip receiving data.

Example embodiments may provide a data transmission device containing a terminal resistance only in a reception chip receiving data.

According to example embodiments, a data transmission device may include a transmission chip, a plurality of reception chips and/or a pair of transmission lines. The transmission chip may be configured to transmit data. The plurality of reception chips may be configured to receive the data from the transmission chip and provide terminal resistance. One of the reception chips may provide the terminal resistance when the one of the reception chips receives the data. The transmission lines may be coupled between the transmission chip and the reception chips, and the transmission lines may have a daisy-chain configuration.

Each of the reception chips may include a pair of input lines, a terminal resistance, a buffer and/or a connection switch. The input lines may respectively branch from the transmission lines. The terminal resistance provision unit may be connected between the input lines. The buffer may receive the data from the input lines. The connection switch may connect the reception chip to an adjacent reception chip.

The terminal resistance provision unit may include a first termination resistor, a second termination resistor and/or a termination switch. The first termination resistor may be connected to a first line of the input lines. The second termination resistor may be connected to a second line of the input lines. The termination switch may connect the first terminal resistor with the second terminal resistor.

A resistance of the first termination resistor may be equal to a resistance of the second termination resistor.

A series resistance of the first termination resistor, the second termination resistor and an on-resistor of the termination switch may be equal to a characteristic impedance of the transmission lines.

The termination switch and the connection switch may be complementarily opened or closed with respect to each other.

Only one of the plurality of reception chips may presently include a token, the one of the plurality of receptions being configured to receive the data from the transmission chip.

The token may be successively provided to the plurality of reception chips from the transmission chip.

A first reception chip of the plurality of reception chips may be electrically connected to a second reception chip of the plurality of reception chips when the second reception chip presently includes the token and the first reception chip included the token prior to the second reception chip.

A first reception chip of the reception chips may be electrically disconnected from a second reception chip of the plurality of reception chips when the first reception chip presently includes the token and the second reception chip will include the token after the first reception chip.

Each of the reception chips may further include a timer configured to control the token.

The transmission chip may be connected with the reception chips in a point-to-point configuration.

The transmission lines may have multi-drop configuration.

According to example embodiments, the data transmission device may further include a connector configured to connect the output terminals of the transmission chip with a first and a second transmission lines. The transmission chip may include a pair of input terminals and a pair of output terminals. The plurality of reception chips may be configured to selectively provide a terminal resistance. The transmission lines may include the first transmission line and the second transmission line in the daisy-chain configuration.

Each of the reception chips may include a first input, a second input line, a driver, a first switching circuit, and/or a second switching circuit. The first and second input lines may respectively branch from the first and the second transmission lines. The driver may be connected to the first and the second input lines. The driver may be configured to receive the data from the transmission lines. The first switching circuit may be connected between the first and the second input lines. The first switching circuit may be configured to be selectively closed based on the data reception of the reception chip to provide the terminal resistance. The second switching circuit may be configured to selectively connect the reception chip to an adjacent reception chip based on the data reception of the reception chip.

The first switching circuit may include a first resistor, a second resistor and a termination switch. The first resistor may be connected to the first input line. The second resistor may be connected to the second input line. The terminal switch may selectively connect the first resistor with the second resistor based on the data reception of the reception chip.

The termination switch and the second switching circuit may be complementarily opened and closed with respect to each other.

According to example embodiments, a method of transmitting data may include receiving data at one of a plurality of reception chips, activating a terminal resistance only at the reception chip receiving the data, and/or deactivating a connection between the reception chip receiving the data and an adjacent reception chip.

Therefore, a data transmission device may provide a fixed terminal resistance in impedance matching and increase a transmission speed.

### BRIEF DESCRIPTION

The above and/or other aspects, and advantages will become more apparent and more readily appreciated from the following detailed description of example embodiments, taken in conjunction with the accompanying drawings, in which:

FIG. 1 is a block diagram illustrating a conventional data transmission device of multi-drop configuration;

FIG. 2 is another block diagram illustrating a conventional data transmission device of multi-drop configuration;

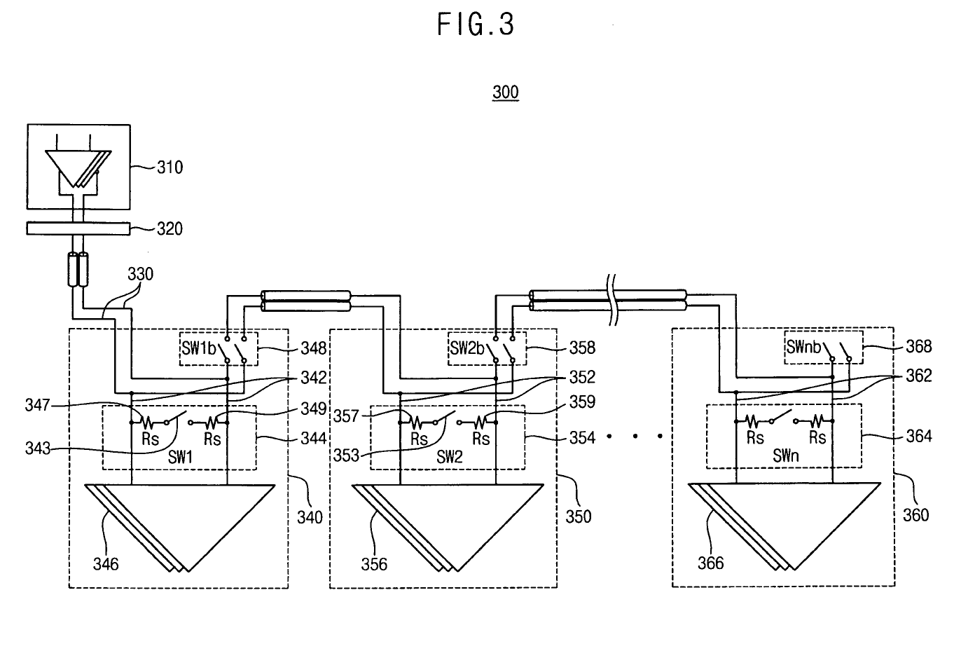

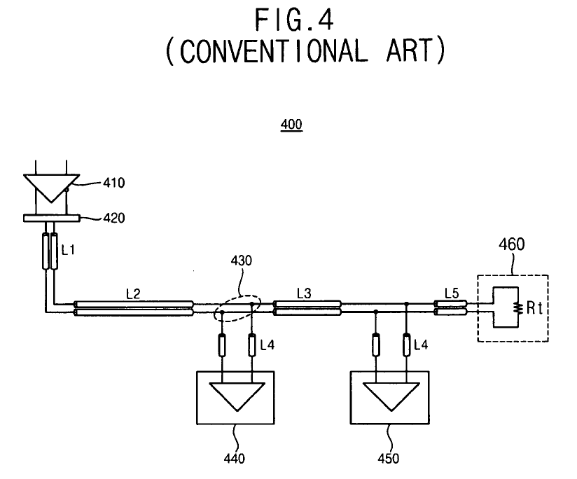

FIG. 3 is a block diagram illustrating a data transmission device according to example embodiments;

FIG. 4 is a block diagram illustrating a conventional data transmission device including two reception units;

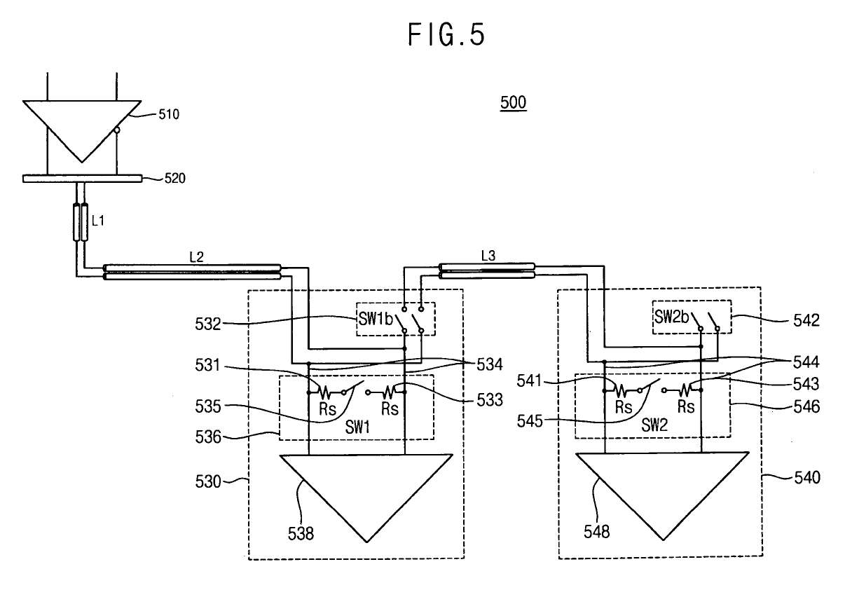

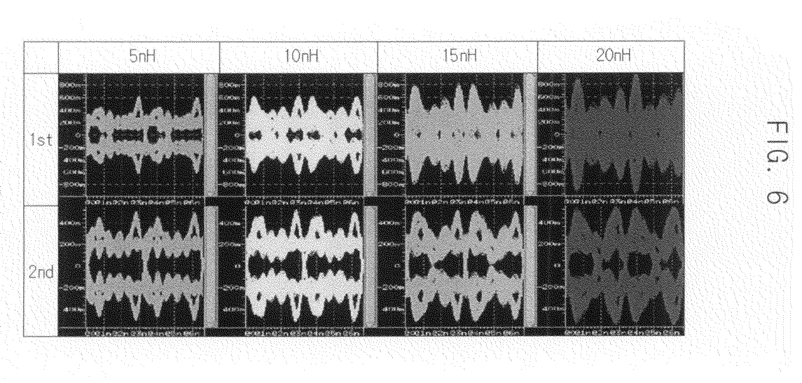

FIG. 5 is a block diagram illustrating a data transmission device including two reception chips according to example embodiments;

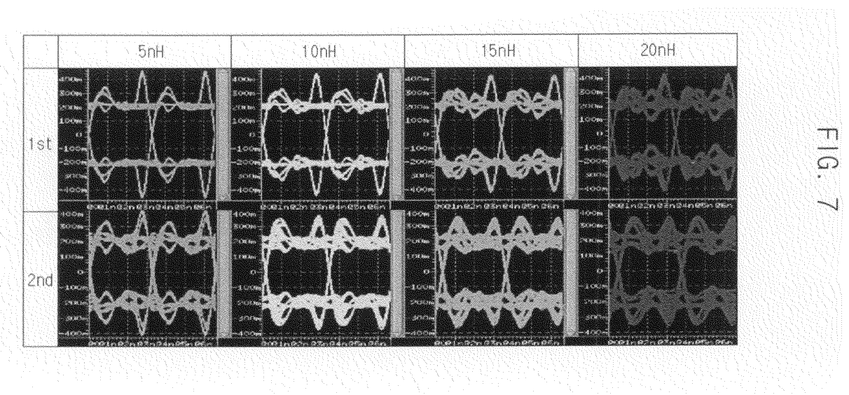

FIG. 6 is a simulation graph illustrating an output voltage characteristic of the first reception unit and the second reception unit in the conventional data transmission device;

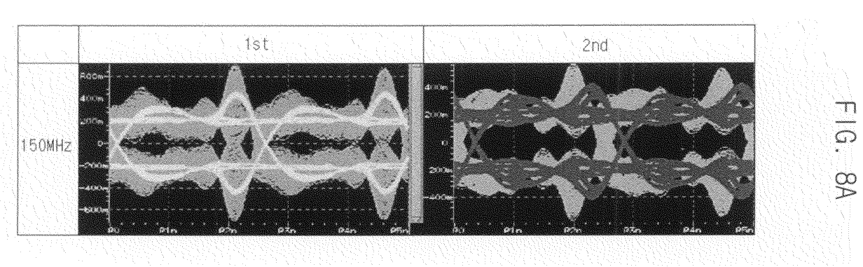

FIG. 7 is a simulation graph illustrating an output voltage characteristic of the first reception chip and the second reception chip in the data transmission device according to example embodiments;

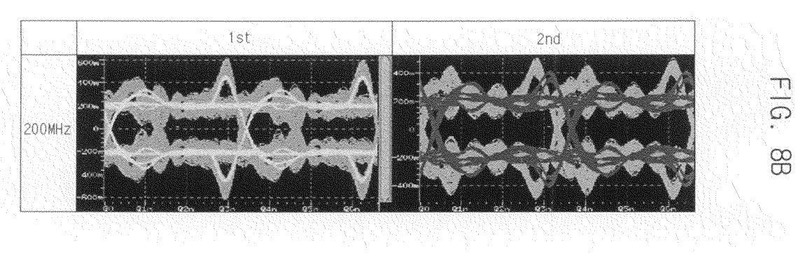

FIG. 8A through FIG. 8C are simulation graphs for comparing an eye-pattern of output voltages according to an increase of a transmission speed; and

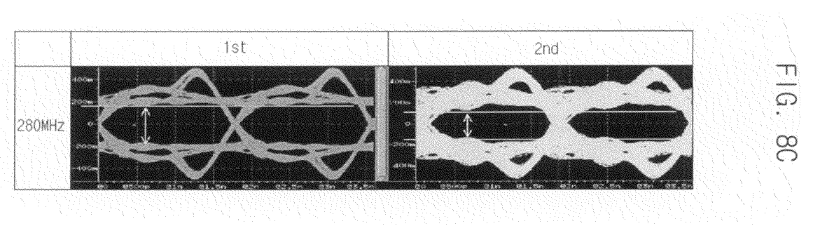

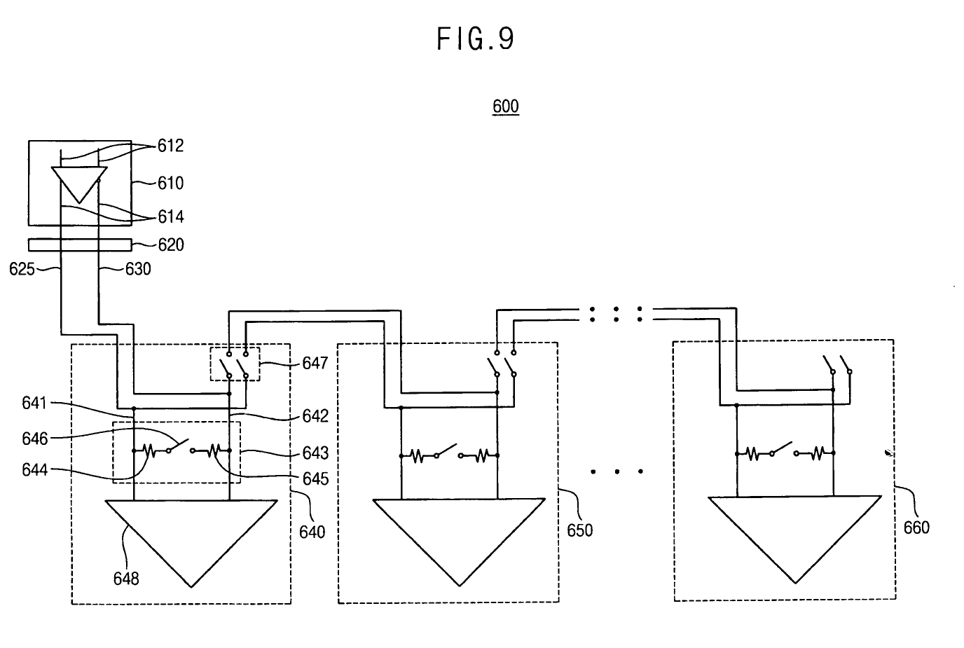

FIG. 9 is another block diagram illustrating a data transmission device of a multi-drop configuration according to example embodiments.

### DETAILED DESCRIPTION

Example embodiments will be described more fully with reference to the accompanying drawings. Example embodiments may, however, be embodied in many different forms and should not be construed as limited to the embodiments set forth herein. Rather, example embodiments are provided so that this disclosure will be thorough and complete, and will fully convey the scope to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 3 is a block diagram illustrating a data transmission device according to example embodiments.

Referring to FIG. 3, a data transmission device 300 may include a transmission chip 310, a plurality of reception chips 340, 350 and 360 and a pair of transmission lines 330. The data transmission device 300 may further include a connector 320 connecting the transmission chip 310 with the transmission lines 330.

The transmission chip 310 may transmit data, and the reception chips 340, 350 and 360 may receive the data from the transmission chip 310 through transmission lines 330. The transmission lines 330 may be a daisy-chain configuration.

Each of the reception chips 340, 350 and 360 may include a pair of input lines 342, 352 and 362, terminal resistance provision units 344, 354 and 364, buffers 346, 356 and 366 and connection switches 348, 358 and 368. The connection switch 368 may be omitted if the reception chip 360 is the last chip.

Each of the input lines 342, 352 and 362 may respectively branch from the transmission lines 330. Each of the terminal resistance provision units 344, 354 and 364 may be connected between the input lines 342, 352 and 362. Each of the buffers 346, 356 and 366 may receive the data by connecting to the input lines 342, 352 and 362. Each of the connection switches 348, 358 and 368 may connect each of the reception chips to an adjacent reception chip.

The terminal resistance provision unit 344 may include a first termination resistor 347, a second termination resistor 349 and a termination switch 343. The first termination resistor 347 may be connected to a first line of the input lines 342, the second termination resistor 349 may be connected to a second line of the input lines 342, and the termination switch 343 may connect the first termination resistor 347 with the second termination resistor 349. A configuration of each of the other terminal resistance provision units 354 and 364 may be similar to a configuration of the terminal resistance provision unit 344.

A resistance of the first termination resistor 347 may be equal to a resistance of the second termination resistor 349. A resistance of the terminal resistance provision unit 344 may be equal to a characteristic impedance of the transmission lines 330.

Of the reception chips 340, 350 and 360, determining which reception chip receives the data may be determined by a token provided from the transmission chip 310.

For example, only one reception chip may include the token, and thus receive the data. Also, only the reception chip receiving the data may activate a terminal resistance by closing the corresponding termination switch 343, 353 or 363.

The token may be successively provided to the reception chips 340, 350 and 360 from the transmission chip 310, and each of the reception chips 340, 350 and 360 may include a timer for controlling the token. The timer may be a counter configuration.

A first reception chip of the reception chips 340, 350 and 360 may be electrically connected to a second reception chip of the reception chips 340, 350 and 360 when the second reception chip presently includes the token and the first reception chip previously included the token prior to the second reception chip.

The second reception chip may be electrically disconnected from a third reception chip of the reception chips 340, 350 and 360 when the second reception chip presently includes the token and the third reception chip will include the token after the second reception chip.

The termination switch 343 and the connection switch 348 may be complementarily opened or closed.

When the reception chip 340 presently includes the token and the reception chip 350 will include the token after the reception chip 340, the termination switch 343 may be closed, and thus the terminal resistance provision unit 344 may provide a terminal resistance of 2Rs+Rsw (where Rsw is the on-resistance of the termination switch 343) that is equal to the characteristic impedance of the transmission lines 330. Additional impedance, other than that of the terminal resistance provision unit 344, may not be caused because the connection switch 348 is open.

A terminal resistance of the data transmission device 300 may be 2Rs+Rsw when the termination switch 353 of the terminal resistance provision unit 354 is closed, and the connection switch 358 of the reception chip 350 is open. The connection switch 348 of the reception chip 340 may be closed and the termination switch 343 of the terminal resistance provision unit 344 may be open when the reception chip 350 receives the data. That is, the terminal resistance of the data transmission device 300 may be 2Rs+Rsw when any of the reception chips 340, 350 and 360 receives the data. Therefore, the data transmission device 300 may provide the terminal resistance equal to the characteristic impedance of the transmission lines 330 since the terminal resistance may be provided only in the reception chip receiving the data.

FIG. 4 is a block diagram illustrating a conventional data transmission device including two reception units.

Referring to FIG. 4, the conventional data transmission device 400 may include a transmission unit 410, a connector 420, transmission lines L1, L2, L3 and L5, via-connects 430, stubs L4, a first reception unit 440, a second reception unit 450, and a termination unit 460. The termination unit 460 may include a termination resistor Rt. The first reception unit 440 and the second reception unit 450 may be source drivers in a flat display device.

FIG. 5 is a block diagram illustrating a data transmission device including two reception chips according to example embodiments.

Referring to FIG. 5, a data transmission device 500 may include a transmission chip 510, a connector 520, transmission lines L1, L2 and L3, a first reception chip 530 and a second reception chip 540.

The first reception chip 530 may include a pair of input lines 534, a terminal resistance provision unit 536, a buffer 538 and a connection switch 532. The terminal resistance provision unit 536 may include a first termination resistor 531, a second termination resistor 533 and a termination switch 535. The second reception chip 540 may include a pair of input lines 544, a terminal resistance provision unit 546, a buffer 548 and a connection switch 542. The terminal resistance provision unit 546 may include a first termination resistor 541, a second termination resistor 543 and a termination switch 545. An operation of each component in the data transmission device 500 may be equal to an operation of the corresponding component in the data transmission device 300.

Hereinafter, simulation results may be described where a length of the transmission line L1 is 0.5 cm, a length of the transmission line L2 is 37 cm, a length of the transmission line L3 is 7.4 cm, a length of the transmission line L4 is 1.5 cm, and a length of the transmission line L5 is 1 cm.

FIG. 6 is a simulation graph illustrating an output voltage characteristic of the first reception unit 440 and the second reception unit 450 in the conventional data transmission device 400.

Referring to FIG. 6, the output voltage characteristic of the first reception unit 440 that is far from a termination resistor Rt may be degraded. A ringing noise may increase according to an increase of a package inductance.

FIG. 7 is a simulation graph illustrating an output voltage characteristic of the first reception chip 530 and the second reception chip 540 in the data transmission device 500 according to example embodiments.

Referring to FIG. 7, a terminal resistance of the first reception chip 530 may be substantially equal to a terminal resistance of the second reception chip 540 although the package inductance increases. The output voltage characteristic of the first reception chip 530 may be improved compared to the output voltage characteristic of the second reception chip 540 because a length of the transmission lines connecting to the second reception chip 540 may be longer than the transmission lines connecting to the first reception chip 530. The ringing noise may not have increased although the package inductance increases.

FIG. 8A through FIG. 8C are simulation graphs for comparing an eye-pattern of output voltages of the first reception unit 440 and the first reception chip 530, and the second reception unit 450 and the second reception chip 540 according to an increase of a transmission speed. In FIG. 8C, only a simulation graph of the data transmission device in FIG. 5 is illustrated.

Referring to FIG. 8A through FIG. 8C, the eye-pattern of the second reception chip 540 may be worse than the eye-pattern of the first reception chip 530 as the transmission speed increases. However, the data transmission device 500 may provide about a 50% or higher ratio of the eye-pattern although the transmission speed is about 150 MHz in FIG. 8A, 200 MHz in FIG. 8B and 280 MHz in FIG. 8C.

FIG. 9 is another block diagram illustrating a data transmission device of a multi-drop configuration according to example embodiments.

Referring to FIG. 9, a data transmission device 600 may include a transmission chip 610, a connector 620, a first transmission line 625, a second transmission line 630 and a plurality of reception chips 640, 650 and 660.

The transmission chip may include a pair of input terminals 612 and a pair of output terminals 614.

The connector 620 may connect the output terminals 614 to the first transmission line 625 and the second transmission line 630.

The reception chip 640 may include a first input line 641, a second input line 642, a first switching circuit 643, a second switching circuit 647 and a driver 648. The first input line 641 may branch from the first transmission line 625 and the second input line 642 may branch from the second transmission line 630.

The first switching circuit 643 may be connected between the first input line 641 and the second input line 642. The first switching circuit 643 may include a first resistor 644, a second resistor 645 and a termination switch 646. The first resistor 644 may be connected to the first input line 641 and the second resistor 645 may be connected to the second input line 642. The termination switch 646 may connect the first resistor 644 with the second resistor 645 when the reception chip 640 receives data. Resistance of the first resistor 644 may be equal to the second resistor 645 as Rs.

The second switching circuit 647 may selectively connect the reception chip 640 with an adjacent reception chip 650 based on the data reception of the reception chip 640. That is, the second switching circuit 647 may electrically disconnect the reception chip 640 from the adjacent reception chip 650 when the reception chip 640 receives the data. Therefore, the termination switch 646 and the second switching circuit 647 may be complementarily opened or closed with respect to each other. In other words, if one switch is closed, then the other switch may be opened.

Configurations and operations of the reception chips 650 and 660 may be similar to those of the reception chip 640.

When the reception chip 640 presently includes a token and receives the data, the termination switch 646 may be closed and the second switching circuit 647 may be open. Therefore, a terminal resistance may be about 2Rs+Rsw (where Rsw is the on-resistance of the termination switch 646). A reflected wave may be prevented through such impedance matching and a transmission speed may be increased when the terminal resistance is equal to a characteristic impedance of the transmission lines 625 and 630. The terminal resistance may be determined to be substantially the same value, although any reception chip of the reception chips 640, 650 and 660 may receive the data.

The transmission chip 610 may be connected to a reception chip receiving the data in a point-to-point configuration. A reception chip including the token may receive the data and the token may be successively provided to the reception chips 640, 650 and 660 from the transmission chip 610.

As described above, a data transmission device may connect a transmission chip with a plurality of reception chips in a daisy-chain configuration, where only one of the plurality of reception chips that receives data may provide a terminal resistance. Each of the reception chips may include a switch for controlling the terminal resistance, and only the reception chip including a token may receive the data and provide the terminal resistance. The data transmission device according to example embodiments may connect the transmission chip with the reception chips in a point-to-point configuration and increase an operation speed. Therefore, the data transmission device may decrease a number of a transmission lines, a size of a printed circuit board and/or output pins of the transmission chip.

Having thus described example embodiments, it is to be understood that the example embodiments defined by the appended claims are not to be limited by particular details set forth in the above description as many apparent variations thereof are possible without departing from the spirit or scope thereof as hereinafter claimed.

What is claimed is:

1. A data transmission device comprising:
a transmission chip configured to transmit data;
a plurality of reception chips configured to receive the data from the transmission chip and provide a terminal resistance, with one of the plurality of reception chips providing the terminal resistance when the one of the plurality of receptions chips receives the data; and
a pair of transmission lines coupled between the transmission chip and the reception chips, the transmission lines having a daisy-chain configuration.

2. The data transmission device of claim 1, wherein each of the plurality of reception chips includes,
a pair of input lines respectively branching from the transmission lines;
a terminal resistance provision unit connected between the input lines;
a buffer configured to receive the data from the input lines; and
a connection switch configured to connect the reception chip to an adjacent reception chip.

3. The data transmission device of claim 2, wherein the terminal resistance provision unit includes,
a first termination resistor connected to a first line of the input lines;
a second termination resistor connected to a second line of the input lines; and
a termination switch configured to connect the first termination resistor with the second termination resistor.

4. The data transmission device of claim 3, wherein a resistance of the first termination resistor is equal to a resistance of the second termination resistor.

5. The data transmission device of claim 4, wherein a series resistance of the first termination resistor, the second termination resistor and an on-resistance of the termination switch is equal to a characteristic impedance of the transmission lines.

6. The data transmission device of claim 3, wherein the termination switch and the connection switch are complementarily opened or closed with respect to each other.

7. The data transmission device of claim 3, wherein only one of the plurality of reception chips presently includes a token, the one of the plurality of reception chips being configured to receive the data from the transmission chip.

8. The data transmission device of claim 7, wherein the token is successively provided to the plurality of reception chips from the transmission chip.

9. The data transmission device of claim 8, wherein a first reception chip of the plurality of reception chips is electrically connected to a second reception chip of the plurality of reception chips when the second reception chip presently includes the token and the first reception chip included the token prior to the second reception chip.

10. The data transmission device of claim 8, wherein a first reception chip of the reception chips is electrically disconnected from a second reception chip of the plurality of reception chips when the first reception chip presently includes the token and the second reception chip will include the token after the first reception chip.

11. The data transmission device of claim 7, wherein each of the reception chips further includes a timer configured to control the token.

12. The data transmission device of claim 3, wherein the transmission chip is connected with the plurality of reception chips in a point-to-point configuration.

13. The data transmission device of claim 1, wherein the transmission lines have a multi-drop configuration.

14. The data transmission device of claim 13, further comprising:
a connector configured to connect output terminals of the transmission chip with a first and a second transmission lines, wherein
the transmission chip includes a pair of input terminals and a pair of output terminals;
the plurality of reception chips are configured to selectively provide the terminal resistance; and
the transmission lines include the first transmission line and the second transmission line in the daisy-chain configuration.

15. The data transmission device of claim 14, wherein each of the reception chips include,
first and second input lines respectively branching from the first and the second transmission lines;
a driver connected to the first and the second input lines, the driver being configured to receive the data from the transmission lines;
a first switching circuit connected between the first and the second input lines, the first switching circuit being configured to be selectively closed based on the data reception of the reception chip to provide the terminal resistance; and
a second switching circuit configured to selectively connect the reception chip to an adjacent reception chip based on the data reception of the reception chip.

16. The data transmission device of claim 15, wherein the first switching circuit includes,
a first resistor connected to the first input line;
a second resistor connected to the second input line; and
a termination switch configured to selectively connect the first resistor with the second resistor based on the data reception of the reception chip.

17. The data transmission device of claim 16, wherein the termination switch and the second switching circuit are complementarily opened and closed with respect to each other.

18. The data transmission device of claim 16, wherein a resistance of the first resistor is equal to a resistance of the second resistor, and a resistance of the first switching circuit is equal to a characteristic impedance of the first and the second transmission lines when the termination switch is closed.

19. The data transmission device of claim 18, wherein the transmission chip is connected with the reception chips in a point-to-point configuration.

20. The data transmission device of claim 14, wherein only one of the plurality of reception chips presently includes a token, the one of the plurality of receptions being configured to receive the data from the transmission chip.

21. A method of transmitting data comprising:
receiving data at one of a plurality of reception chips;
activating a terminal resistance only at the reception chip receiving the data; and
deactivating a connection between the reception chip receiving the data and an adjacent reception chip.
